(19) United States
(12) Patent Application Publication
(10) Pub. No.: US 2002/0089435 A1
(43) Pub. Date: Jul. 11, 2002

(54) Method and apparatus for inputting characters, and storage medium

(76) Inventors: Takashi Hanamoto, Kanagawa (JP); Kunihiro Yamamoto, Kanagawa (JP); Kiyoshi Kusama, Tokyo (JP)

Correspondence Address: ROBIN BLECKER & DALEY, 2ND FLOOR, 330 MADISON AVENUE, NEW YORK, NY, 10017, US

(21) Appl. No.: 10/011,502

(22) Filed: Oct. 22, 2001

(30) Foreign Application Priority Data
Oct. 27, 2000 (JP) 329639/2000

(51) Int. Cl. H03M 11/00; H03K 17/94

(52) U.S. Cl. 341/20

(57) ABSTRACT

There are disclosed a method and an apparatus for inputting characters, capable of saving the space of a character input screen and facilitating character inputting, and a storage medium. When the information of a character to be input is selected and input by scrolling a character selection portion displaying predetermined character information to be displayed on the character inputting position of an input result display portion, the input character information is displayed on the input result display portion, and the character selection portion is moved to a next character information inputting position.

### BACKGROUND OF THE INVENTION

1. Field of the Invention

The present invention relates to a method and an apparatus for inputting characters, and a storage medium. More particularly, the present invention relates to a method and an apparatus for inputting characters by using a remote controller, and a storage medium.

2. Description of the Related Art

According to one of the conventionally available methods for inputting characters by using a remote controller, a game machine controller, and so on, as shown in FIG. 14, a character is input by displaying a character input screen 201 setting forth alphabets on the display screen of a television set, a monitor or the like, operating ten keys on the remote controller, or the like, and moving a cursor 202 to the character to be input.

Other methods have also been presented, for example one disclosed in Japanese Patent Application Laid-Open No. 09-289595, which facilitates character inputting by arranging special buttons for inputting characters on a remote controller.

However, in the foregoing conventional method for inputting characters, function keys for changing a character type, deleting characters, and so on, had to be selected and, each time, the cursor 202 was moved many times. Thus, the operation was troublesome for a user. Especially, when the same word was input many times, it was inconvenient because the same operation had to be repeated over and over.

On the other hand, in the case of the character inputting method including the special buttons arranged on the remote controller to facilitate character inputting, the number of buttons on the remote controller was increased, consequently obstructing operations other than character inputting.

Furthermore, in the conventional method for inputting characters, the characters set forth on the screen occupied most of the area thereof, necessitating the screen for inputting characters to be enlarged.

The present invention was made with the foregoing problems in mind, and objects of the present invention are to provide a method and an apparatus for inputting characters, capable of saving a screen space for character inputting, and facilitating character inputting without increasing the number of buttons on a remote controller, and a storage medium.

### SUMMARY OF THE INVENTION

In order to achieve the foregoing object, according to an aspect of the present invention, there is provided a method for inputting characters by using a plurality of buttons, comprising: a character selecting step of selecting desired characters by scrolling a predetermined character string, and aligning the desired characters with an inputting position; and a character inputting step of inputting the selected characters. In this case, the selection portion is moved in association with the input characters when the characters are input in the character inputting step.

In order to achieve the foregoing object, according to another aspect of the invention, there is provided an apparatus for inputting characters, comprising: inputting means for inputting characters by using a plurality of buttons; displaying means for displaying the input characters on a screen; character selecting means for selecting desired characters by scrolling a predetermined character string of a selection portion on the screen, and aligning the desired characters with an inputting position; and character inputting means for inputting the selected characters. In this case, when the characters are input by the character inputting means, the character selecting means is moved in association with the input characters.

In order to achieve the foregoing object, according to another aspect of the invention, there is provided a storage medium storing a program for carrying out a method for inputting characters by using a plurality of buttons, and enabling the program to be read, comprising: a character selection module for selecting desired characters by scrolling a predetermined character string, and aligning the desired characters with an inputting position; and a character inputting module for inputting the selected characters. In this case, the character selection module is moved in association with the input characters when the characters are input by the character inputting module.

In order to achieve the foregoing object, according to yet another aspect of the invention, there is an apparatus for inputting characters, comprising: a character information input area; a display area for displaying information of a character to be selected on a character inputting position of the character information input area; scrolling means for scrolling the information of the character to be selected in the display area; and moving means for inputting, to the character information inputting position, character information displayed on a predetermined position of the display area by scrolling of said scrolling means, and moving the display area to a next character information inputting position.

In order to achieve the foregoing object, according to a further aspect of the invention, there is provided a method for inputting characters, comprising: a scrolling step of scrolling information of a character to be selected in a display area for displaying the information of the character to be selected on a character inputting position of a character information inputting area; and a moving step of inputting, to the character information inputting position, character information displayed on a predetermined position of the display area by scrolling of the scrolling step, and moving the display area to a next character information inputting position.

In order to achieve the foregoing object, according to yet further aspect of the invention, there is provided a storage medium for enabling a program to be read, the program being used to carry out a control method of an input apparatus, comprising: a scrolling module for scrolling information of a character to be selected in a display area for displaying the information of the character to be selected in a character inputting position of a character information input area; and a moving module for inputting, to the character information inputting position, character information displayed on a predetermined position of the display area by scrolling of the scrolling module, and moving the display area to a next character information inputting position.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a block diagram schematically showing a configuration of a character inputting apparatus for carrying out a character inputting method according to an embodiment of the invention.

FIGS. 2A and 2B are schematic views of an input device 101 of FIG. 1:

FIG. 2A showing its appearance; and

FIG. 2B a list of functions of buttons provided in the input device 101.

FIG. 3 is a schematic view showing a content displayed on a screen during character inputting.

FIGS. 4A and 4B are schematic views of operations performed when a character is selected at a character selection portion 402:

FIG. 4A showing a display screen when a scrolling-up operation is performed; and

FIG. 4B a display screen when a scrolling-down operation is performed.

FIGS. 5A and 5B are schematic views of operations performed when a character type of a character string is changed at the character selection portion 402:

FIG. 5A showing a list of character types to be changed; and

FIG. 5B a display screen when a character type is changed.

FIG. 6 is a flowchart of a character inputting process carried out by a character inputting method according to a first embodiment.

FIGS. 7A and 7B are schematic views of an input result display 401 and a character selection screen 402 in the process of FIG. 6:

FIG. 7A showing the character selection portion 402 during character selection; and

FIG. 7B the input result display portion 401 and the character selection portion 402 during character inputting.

FIG. 8 is a flowchart of a character deletion process carried out by a character inputting method according to a second embodiment.

FIG. 9 is a schematic view of a display screen of the process shown in FIG. 8.

FIG. 10 is a flowchart of a character string inputting process carried put by an incremental search function of a character inputting method according to a third embodiment.

FIG. 11 is a schematic view of a display screen of the process shown in FIG. 10.

FIG. 12 is a flowchart of a character string inputting process carried out by list displaying of character strings input in the past by a character inputting method according to a fourth embodiment.

FIG. 13 is a schematic view of a display screen of the process shown in FIG. 12.

FIG. 14 is a schematic view of a display screen by a conventional character inputting method.

### DETAILED DESCRIPTION OF THE PREFERRED EMBODIMENTS

Preferred embodiments of the present invention will now be described in detail in accordance with the accompanying drawings.

First Embodiment

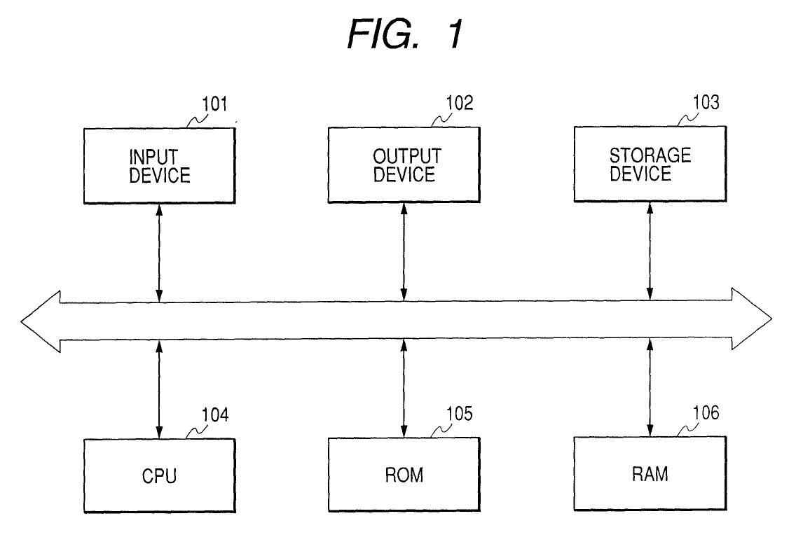

FIG. 1 is a block diagram schematically showing the configuration of a character inputting apparatus for executing a character inputting method according to the first embodiment of the invention.

In FIG. 1, a reference numeric 101 denotes an input device for accepting input instruction by a user and a data entry, specifically designed to receive an input signal from a remote controller; 102 an output device for performing screen displaying by Graphical User Interface (GUI) during character inputting, normally a television set, a CRT monitor for a personal computer (PC), a liquid crystal display or the like being used therefore; and 103 a storage device for recording/storing a program for character inputting, normally a hard disk or the like being used therefore.

The control of each of the above-described devices is performed by a CPU 104. A ROM 105 and a RAM 106 are memories for storing a program necessary for processing of the CPU 104, data on a character string input in the past, and so on. Especially, the RAM 106 provides a work area for the CPU 104. The program for carrying out the character inputting method of the embodiment is normally stored in the storage device 103. However, such a program may be stored in the ROM 105. If there is a program stored in the storage device 103, the program is first read in the RAM 106, and then executed. In addition, in the storage device 103, there is stored a predetermined database used for later-described incremental search. The database is composed of English words or the like. The configuration of the embodiment comprises various other components, but description thereof will be omitted because they are not principal objects of the invention.

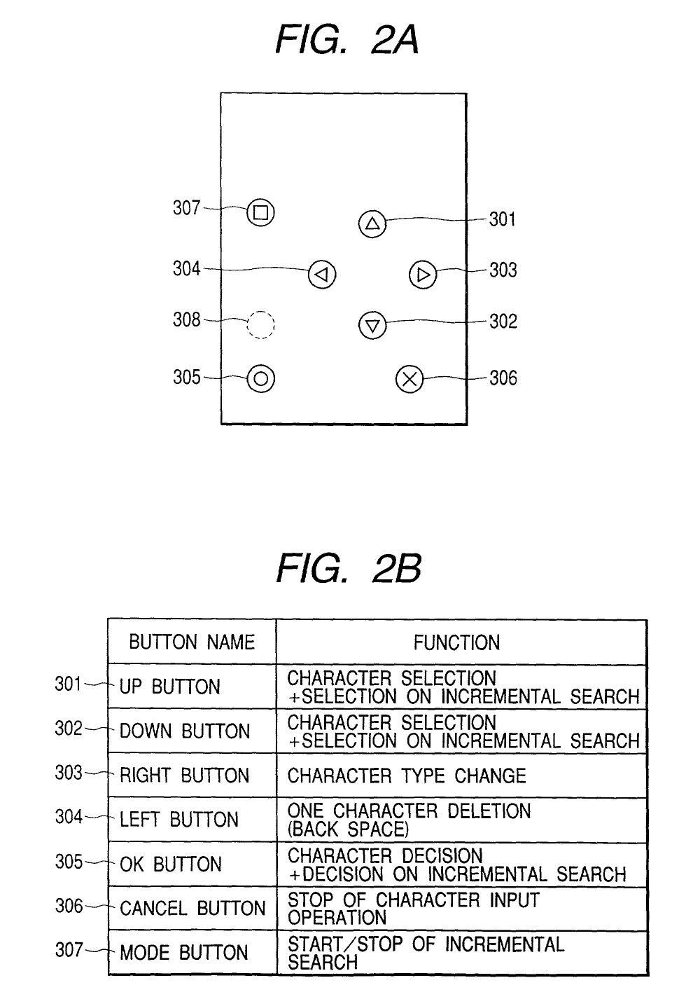

FIGS. 2A and 2B are schematic views of a remote controller for sending a signal to the input device 101 of FIG. 1: FIG. 2A showing its appearance; and FIG. 2B a list of button functions provided in the remote controller for sending a signal to the input device 101.

In FIG. 2A, the remote controller for sensing a signal to the input device 101 includes seven buttons on its surface, and various functions for later-described character inputting are allocated to the respective buttons. Character selection and inputting are carried out by pressing the buttons.

In FIG. 2B, an up button 301 has a character selecting function allocated to scroll up a predetermined character string displayed on the display screen of the output device 102, and a selecting function allocated to be used for incremental search. A down button 302 has a character selecting function allocated to scroll down a predetermined character string, and a selecting function allocated to be used for incremental search. A right button 303 has a character type changing function allocated to change a plurality of character types including an alphabet capital letter, an alphabet small letter, a numeric, and a symbol. A left button 304 has a one-character deleting (back space) function, and an OK button 305 has a character deciding function, and a deciding function allocated to be used for incremental search. A Cancel button 306 a function allocated to stop a character inputting operation, and a Mode button 307 has a function allocated to start/stop incremental search.

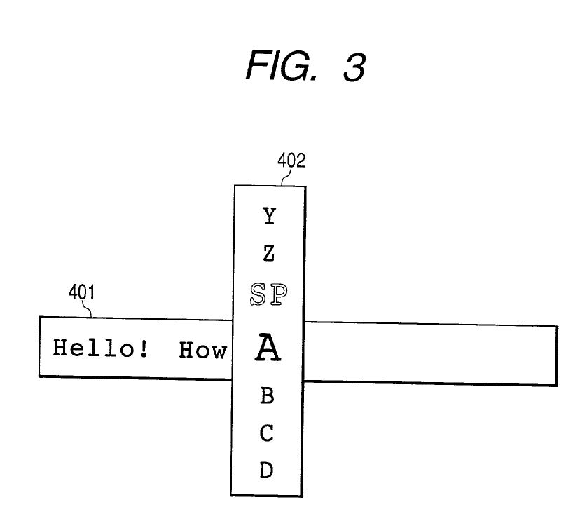

FIG. 3 is a schematic view showing a content displayed on the screen during character inputting.

In FIG. 3, an input result display portion 401 displays an input character string. A character selection portion 402 displays a predetermined character string for the purpose of selecting a character to be input. A character selected by the character selection portion 402 is output and displayed on the input result display portion 401. A large character in the center of the character selection portion 402 indicates currently selected one. Any optional input result display portion 401 is used as long as it can display a text.

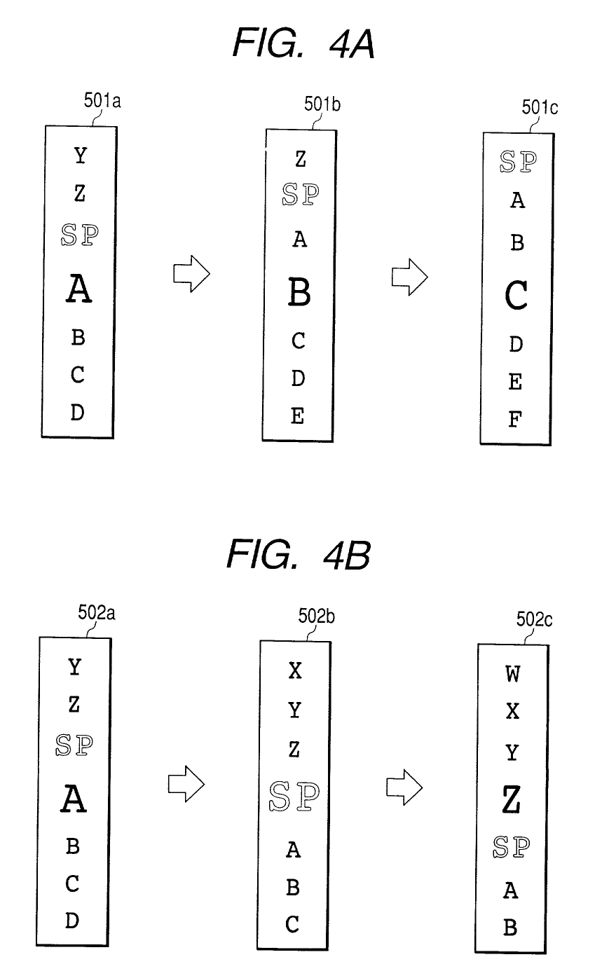

FIGS. 4A and 4B are schematic views showing operations performed when a character is selected by the character selection portion 402: FIG. 4A showing a display screen when a scrolling-up operation is performed; and FIG. 4B a display screen when a scrolling-down operation is performed.

The character selection portion 402 can select an optional character by operating the above-described remote controller so as to scroll-up or down a character string displayed on the screen. In FIGS. 4A and 4B, character strings composed of alphabet capital letters A to Z and “SP” are displayed. “SP” is a later-described function character, meaning a null space.

In FIG. 4A, the scrolling-up operation is carried out by pressing the up button 301 of the remote controller shown in FIG. 2A. The character string is scrolled-up when the up button 301 is pressed once, and a selected character is accordingly changed from “A” to “B” (501a to 501b). When the up button 301 is pressed again, the character string is further scrolled-up, and the selected character is changed to “C” (501b to 501c).

In FIG. 4B, the scrolling-down operation is carried out by pressing the down button 302 of the remote controller shown in FIG. 2A. The character string is scrolled-down when the down button 302 is pressed once, and a selected character is accordingly changed from “A” to “SP” (502a to 502b). The character string is further scrolled-down when the down button 302 is pressed, and the selected character is changed to “Z” (502b to 502c). Thus, by performing scrolling-up/down operation, it is possible to select an optional character from the character string composed of “A” to “Z” and “SP”.

In place of scrolling carried out character by character, scrolling may be performed for every plurality of character strings, e.g., seven characters. For example, as indicated by a dotted line of FIG. 2A, a next group of character strings may be scrolled by adding one button to the remote controller, and pressing a button 308.

In addition, instead of pressing the button once for each scrolling, continuous scrolling may be performed by keep pressing the button.

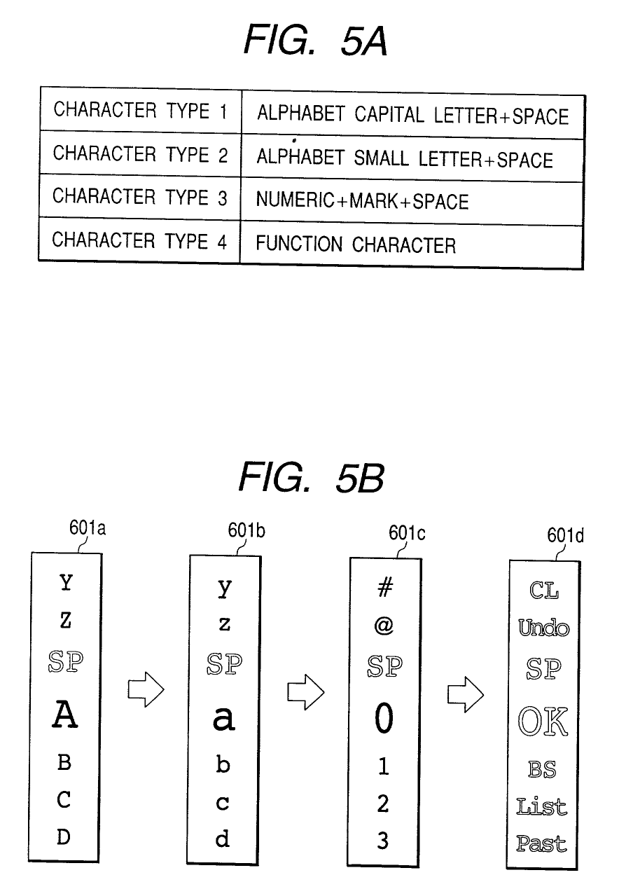

FIGS. 5A and 5B are schematic views showing operations performed when the character type of a character string is changed at the character selection portion 402: FIG. 5A showing a list of changeable character types; and FIG. 5B a display screen when a character type is changed.

In addition to the operation of selecting an optional character from the foregoing character string composed of the alphabet capital letters “A” to “Z” and “SP” by operating the remote controller, the character selection portion 402 can perform the operation of changing a character string to one of the other character types, i.e., alphabet small letters, a numeric, a symbol, and so on. The character selection portion 402 can select four kinds of character types as shown in FIG. 5A.

In FIG. 5A, a character type I is composed of an alphabet capital letter and “SP”; a character type 2 an alphabet small letter and “SP”; a character type 3 a numeric, a symbol and “SP”; and a character type 4 a function character having a function. In addition, each character type includes a function character for inputting a null into a character string to be input.

The function character is used to execute a specific function, and includes “OK” (notify the completion of character string inputting to the system), “BS” (delete one character of right end of an input character string”, “SP” (insert null), “List” (start increment search), “Past” (display a list of character strings input in the past), “CL” (delete all the input character strings), “Undo” (return an input operation to a start only once), and so on. Especially, the function character is displayed by a color different from that of the other character string so as to be easily differentiated from other characters.

FIG. 5B shows a display screen when a character type is changed. The changing of the character type is carried out by pressing the right button 303 of the remote controller shown in FIG. 2A. First, the character string of a character type 1 at 601a is changed to that of a character type 2 (601b) by pressing the right button 303 of the remote controller once. Further, by pressing the right button 303 twice, the character string is changed in the manner of [the character type 2 (601b)—character string 3 (601c) character string 4 (601d)]. By pressing the right button 303 again, the character string is returned to the character type (601a).

Thus, by performing the operations shown in FIGS. 4A and 4B and FIGS. 5A and 5B in combination, it is possible to select an optional character.

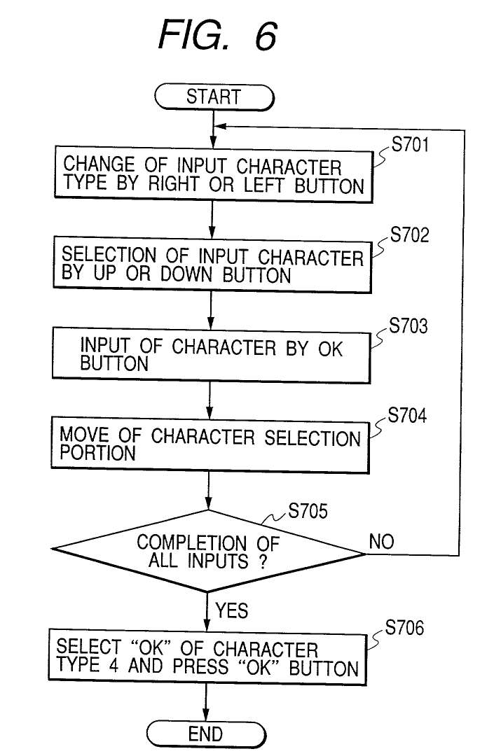

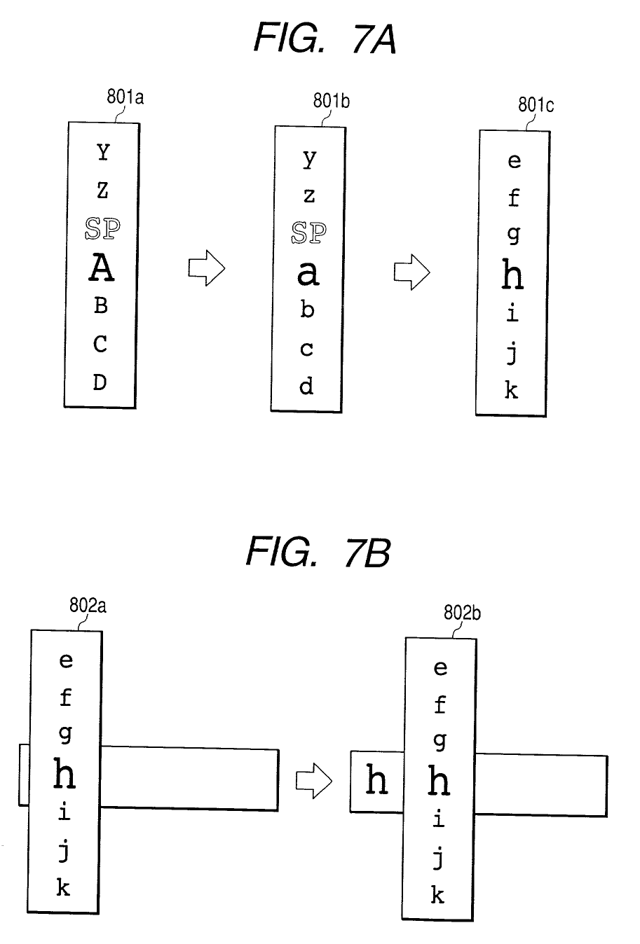

Next, the process of selecting and inputting a character by using the character selection portion 402 will be described by referring to FIG. 6 and FIGS. 7A and 7B.

FIG. 6 is a flowchart showing a character inputting operation carried out in the character inputting method of the first embodiment. FIGS. 7A and 7B are schematic views of the input result display 401 and the character selection screen 402 in the process of FIG. 6: FIG. 7A showing the character selection portion 401 during character selection; FIG. 7B the input result display portion 401 and the character selection portion 402 during character inputting.

In FIG. 6, for example when the character string of a word “hello” is input, first, by pressing the right button 303 or the left button 304 of the remote controller, a character type input by the right/left button is changed (step S701). Here, since “h” is input, by pressing the right button 303 one, a character type 1 (801a of FIG. 7A) is changed to the alphabet small letter of a character type 2 (801b of FIG. 7A). In step S702, the up button 301 or the down button 302 is pressed to scroll-up or down a character string such that a character “h” to be input is located in a center inputting position, and a character to be input is selected by the up or down button. Here, the up button 301 is pressed by seven times such that “h” comes to the center. After the character “h” to be input has come to the center (801c of FIG. 7A), by pressing the OK button 305 of the remote controller, character inputting by the OK button is carried out (step S703). Since the character selected in association with the center inputting position is displayed large, easy selection is possible. Thus, the character “h” located in the center is copied in the input result display portion 401, and displayed (802a to 802b of FIG. 7B).

After the character has been displayed on the input result display portion 401, the character selection portion 402 is moved right (step S704). This movement is made to prevent the impossible displaying/verification of the input character caused by its placement behind the character selecting means 402, and also to facilitate the understanding of a current character inputting position. Then, in step S705, determination is made as to whether the inputting of all the characters has been completed or not. If the result of the determination shows that the remaining characters “ello” have not been input, meaning the inputting of all the characters has not been completed (NO in step S705), the process returns to step S701, and then the process from step S701 to S704 is repeated to input “hello”.

If it is determined that the inputting of all the characters has been completed (YES in step S705), the right button 303 is pressed several times to change to a character type 4 composed of function characters, and “OK” is selected from the character strings of the character type 4. Then, by pressing the OK button 305 (step S706), the process is finished. Thus, compared with the conventional case, character inputting can be carried out more easily without taken any space.

According to the first embodiment, a plurality of character types are changed by the left and right buttons on the remote controller (step S701), a character to be input is selected by the up/down method button (step S702) and, when the character is input by the OK button, the character selection portion 402 is moved in association with the character inputting position. Thus, the space of the character input screen can be saved, and character inputting can be facilitated without increasing the number of buttons on the remote controller.

Second Embodiment

The second embodiment of the present invention includes a character deleting function added to the character inputting method of the first embodiment, and has a configuration similar to that of the first embodiment. Thus, description thereof will be omitted. Hereinbelow, only points different from those of the first embodiment are described.

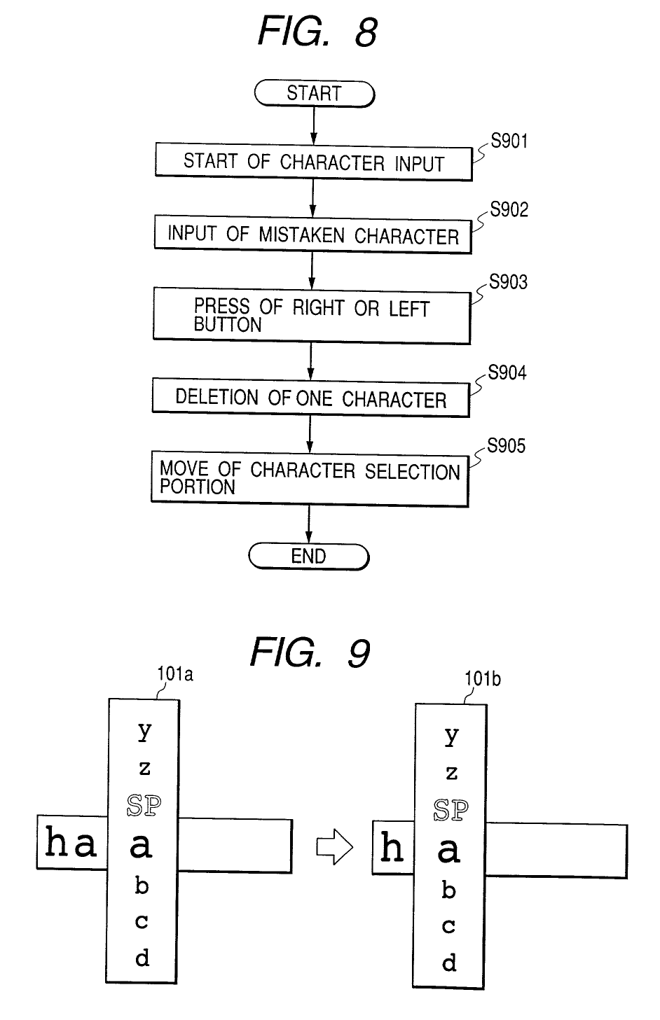

FIG. 8 is a flowchart showing a character deleting process in a character inputting method according to the second embodiment; and FIG. 9 a schematic view of a display screen in the process of FIG. 8.

In FIG. 8, character inputting is started by using the character inputting method described above with reference to FIG. 6 (step S901). Then, if a mistaken character “ha” is input instead of “hello” (step S902), then the left button 304 of the remote controller is pressed once (step S903). Then, a character “a” mistakenly copied and input to an inputting position is subjected to one-character deletion (step S904). The character selection portion 402 is moved left in association with the deleted character (step S905), and the process is finished. Thus, as show by 101a and 101b of FIG. 9, the mistakenly input “a” is deleted, and the character selection portion 402 is moved left, making it possible to carry out correct character inputting.

According to the second embodiment, if a character is mistakenly input (step S902), the character copied and input to the inputting position is subjected to one-character deletion only by pressing the left button 304 once. Thus, the operation of moving the cursor to “BS” many times, necessary in the conventional input device, is made unnecessary, making it possible to facilitate the character inputting operation.

Third Embodiment

The third embodiment includes an incremental search (auto-complete) function using a predetermined database, added to the character inputting method of each of the first and second embodiments, and has a configuration similar to that of each of the first and second embodiments. Thus, description thereof will be omitted. Hereinbelow, only points different from those of the first and second embodiments are described.

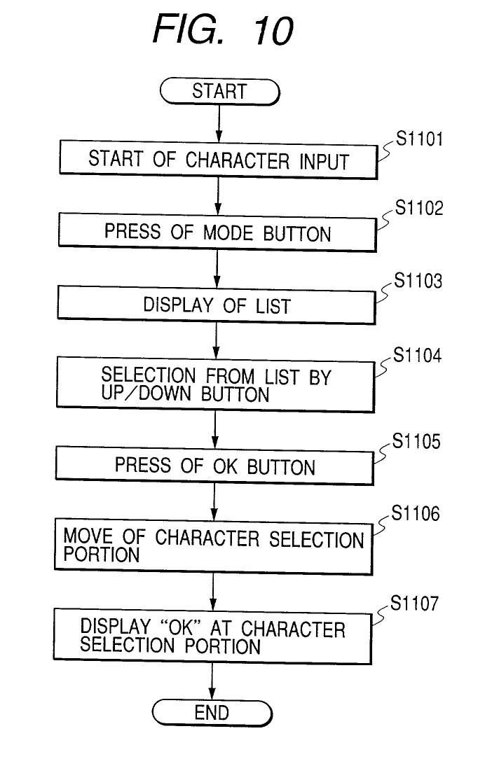

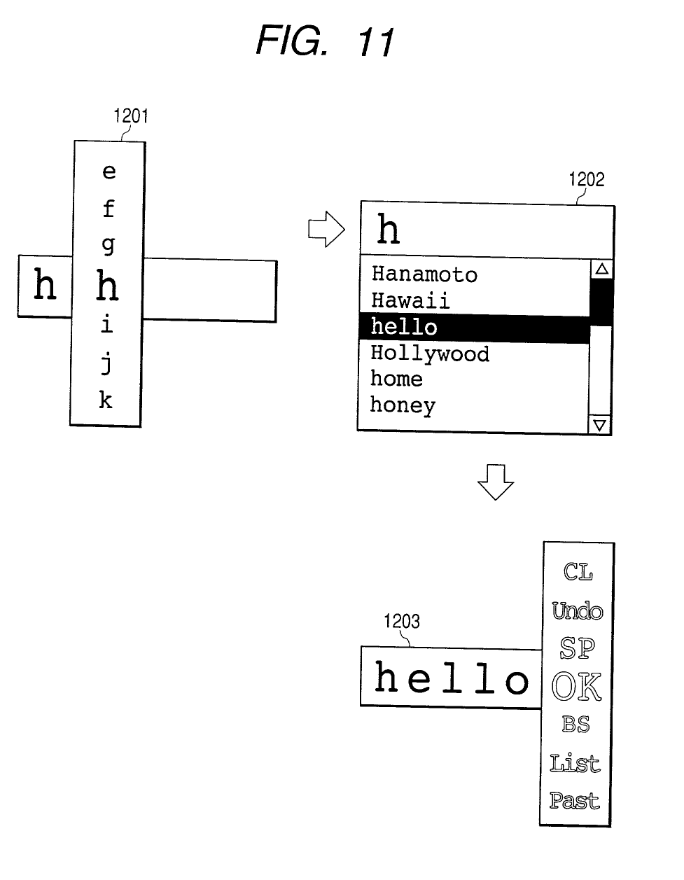

FIG. 10 is a flowchart showing a character string inputting process by the incremental search function of a character inputting method according to the third embodiment; and FIG. 11 a schematic view of a display screen in the process of FIG. 10.

In FIG. 10, character inputting is started for the purpose of inputting a word “hello” in step S1101 (1201 in FIG. 11). After “h” is copied and input to the inputting position by using the character inputting method of the first embodiment, the Mode button 307 of the remote controller of FIG. 2A is pressed (step S1102). Then, with the copied and input “h” as a query, incremental search is executed by using a predetermined database stored in the storage device 103. Subsequently, in step S1103, the result of the incremental search is displayed as a list on the screen (1202 of FIG. 11).

In subsequent step S1104, a target “hello” is selected from the list displayed on the screen by operating the up button 301 or the down button 302. Then, by pressing the OK button 305 of the remote controller, the selected character string “hello” is copied and displayed on the input result display portion 401 (step S1105). Subsequently, after the character selection portion 402 is moved by a necessary amount according to the input character string (step S1106), to enable character inputting to be immediately finished, “OK” is input to the inputting position so as to select a function character “OK” having a function allocated to finish character inputting (step S1107). Thus, when a character string is input by using the incremental search function, a function character can be selected without performing the operation of selecting the function character having the function allocated to finish character inputting. Thus, word inputting can be facilitated.

The character string stored in the database is not limited to one input in the past. Generally used words may be stored, or a character string candidate suited to a situation may be displayed.

According to the third embodiment, for character inputting, the Mode button 307 is pressed to start increment search (step S1102), a necessary word (character string) is selected from the displayed list by the up/down button (step S1104) to carry out character inputting, and the function character can be selected without performing the operation of selecting the function character having the function allocated to finish character inputting. Thus, character inputting can be facilitated.

Fourth Embodiment

The fourth embodiment includes a function of displaying a list of data on character string input in the past, and inputting a desired character string among them, added to the character inputting method of the foregoing embodiment. Thus, the fourth embodiment has a configuration similar to that of the foregoing embodiment, and description thereof will be omitted. Hereinbelow, only points different from those of the foregoing embodiment are described.

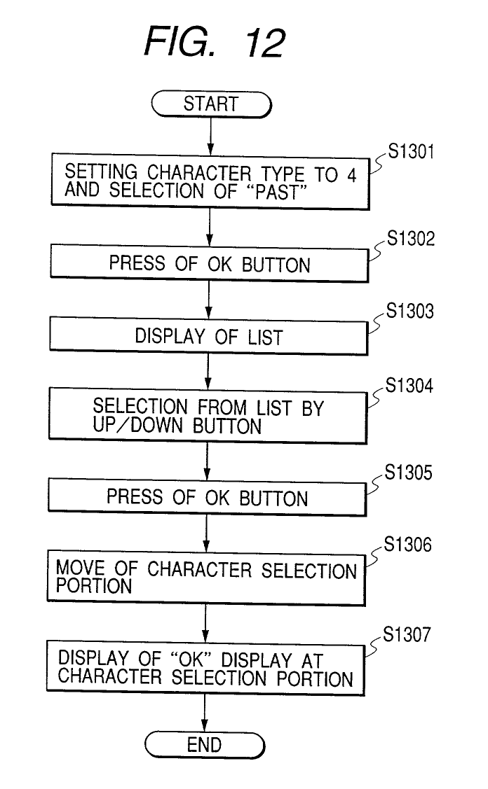

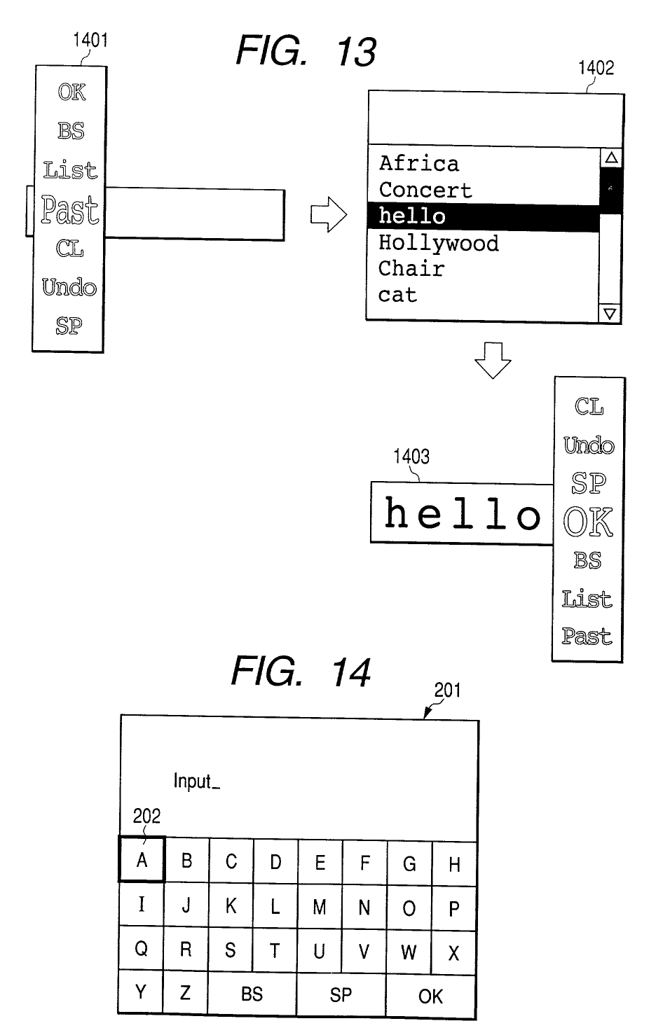

FIG. 12 is a flowchart showing a character inputting process based on the list displaying of character strings input in the past in a character inputting method according to the fourth embodiment; FIG. 13 a schematic view of a display screen in the process of FIG. 12.

In FIG. 12, first, inputting is started for the purpose of inputting a character string “hello”, the right button 303 of the remote controller is pressed by a necessary amount, the character type of the character selection portion 402 is set to 4 and, by pressing the up/down button 301 or 302 by a necessary amount, selection is made such that “Past” comes to the inputting position (step S1301) (1401 of FIG. 13). In subsequent step S1302, by pressing OK button 305 of the remote controller, the data on the character string input in the past is read from a specific file or registry stored in the storage device 103. In step S1303, the read character string is displayed as a list on the screen (1402 of FIG. 13).

In subsequent step S1304, a target “hello” is selected from the list displayed on the screen by using the up button 301 or the down button 302. In step S1305, when the OK button 305 of the remote controller is pressed, the selected character string “hello” is copied and displayed on the input result display portion 401. Then, after the character selection portion 402 is moved in association with the input character string (step S1306), to enable the character inputting to be immediately finished, “OK” is input to the inputting position such that the function character “OK” having a function allocated to finish character inputting can be selected (step S1307) (1403 of FIG. 13).

According to the fourth embodiment, for character inputting, the data on the character strings input in the past are read by pressing “Past” of the selected character type 4 (step S1301 to S1303), the necessary character string is selected from the displayed list by the up/down button (step S1304), and then character inputting is carried out. Thus, by adding the function of easily re-inputting the character string input in the past, character string inputting can be facilitated.

In addition, in the first to fourth embodiments, the character selection portion 402 is moved only left or right. However, when line changing or the like is carried out, the character selection portion may be moved up or down.

(Other Embodiments)

By storing a program for carrying out a control method to realize each of the first to fourth embodiments, stored in the ROM 105 in the character input device, in a optional storage medium to be removed, and loading this storage medium from the outside, the program may be supplied to the CPU 104 and executed. For the storage medium for supplying such a program, for example one may be selected from a floppy disk, a hard disk, an optical disk, a magneto-optical disk, a CD-ROM, a CD-R, a magnetic tape, a nonvolatile memory card, and so on. In addition, in place of the CPU 102, each of the foregoing embodiments may be realized by a not-shown circuit similarly operated.

The character input device may be a PC, and a part or all the programs may be executed by an Operating System (OS) or the like operating on the PC. In addition, the programs supplied by the optional storage medium to be removed may be written in a not-shown function expansion board inserted into the PC or a not-shown memory provided in a not-shown function expansion unit connected to the PC, and then a part or all the programs may be executed by a not-shown CPU or the like provided in the function expansion board or the function expansion unit.

As described in detail above, according to the invention, it is possible to save the space of the character input screen, and to facilitate character inputting without increasing the number of buttons on the remote controller.

Since one of the input characters is deleted by pressing one of the plurality of buttons once, the operation of moving the cursor to the “BS” many times, necessary in the conventional input device, is made unnecessary. Thus, it is possible to facilitate a character inputting operation.

By pressing one of the plurality of buttons once, increment search using a predetermined database based on the selected character type is carried out, and a desired character string is input from the displayed list of the result thereof. Thus, it is possible to input a desired character string by an easy operation.

In addition, by pressing one of the plurality of buttons once, the data on the character strings input in the past are displayed in a list, and a desired character string is input therefrom. Thus, it is possible to input a desired character string by an easy operation.

Furthermore, when a character string is input by incremental search, a function character having a function allocated to finish character inputting is selected. Thus, it is possible to facilitate character string inputting.

What is claimed is:

1. A method for inputting characters by using a plurality of buttons, comprising:
a character selecting step of selecting desired characters by scrolling a predetermined character string of a selection portion, and aligning the desired characters with an inputting position; and
a character inputting step of inputting the selected characters, wherein the selection portion is moved in association with the input characters when the characters are input in said character inputting step.

2. A method for inputting characters according to claim 1, wherein in said character selecting step, a movement is made in a right direction when the characters are input.

3. A method for inputting characters according to claim 1, wherein in said character selecting step, one of the input characters is deleted by pressing one of the plurality of buttons once.

4. A method for inputting characters according to claim 3, wherein in said character selecting step, a movement is made in a left direction when one of the input characters is deleted.

5. A method for inputting characters according to claim 1, wherein said character selecting step includes a storing step of storing data of a character string input in the past, and a predetermined database.

6. A method for inputting characters according to claim 1, wherein in said character selecting step, by pressing one of the plurality of buttons once, incremental search is carried out using the predetermined database based on the selected characters.

7. A method for inputting characters according to claim 1, wherein in said character selecting step, by pressing one of the plurality of buttons once, a list of data of character strings input in the past is displayed, and a desired one among the character strings is input.

8. A method for inputting characters according to claim 6 or 7, wherein in said character selecting step, when the incremental search is carried out, and the desired one in the displayed data list of the character strings input in the past is input, a movement is made only by a necessary amount in association with the input character string.

9. A method for inputting characters according to claim 8, wherein in said character selecting step, when the characters are input, a movement is made in a right direction.

10. A method for inputting characters according to claim 1, wherein in said character selecting step, a plurality of character types including an alphabet capital letter, an alphabet small letter, a numeric and a symbol are displayed as the predetermined character string.

11. A method for inputting characters according to claim 10, wherein the character types include a plurality of function keys for supporting character inputting.

12. A method for inputting characters according to claim 11, wherein for the function keys, at least one or more are allocated, being selected from a function of finishing character inputting, a function of inserting a null into the input character string, a function of deleting one character of a right end of input character string, a function of starting incremental search, a function of displaying a list of the character strings input in the past, a function of deleting all the input character strings, and a function of returning an inputting operation to a start only once.

13. A method for inputting characters according to claim 11, wherein the function keys are displayed by colors different from those of the character types.

14. A method for inputting characters according to claim 1, wherein by pressing one of the plurality of buttons, the displaying of the character types is switched.

15. A method for inputting characters according to claim 10, wherein the predetermined character string includes a function character for inputting a null into the character string.

16. A method for inputting characters according to claim 1, wherein the selected characters are displayed large.

17. A method for inputting characters according to claim 6, wherein when the character string is input by the increment search, a function key having a function allocated to finish the character inputting is selected.

18. An apparatus for inputting characters comprising:
inputting means for inputting characters by using a plurality of buttons;
displaying means for displaying the input characters on a screen;
character selecting means for selecting desired characters by scrolling a predetermined character string of a selection portion on the screen, and aligning the desired characters with an inputting position; and
character inputting means for inputting the selected characters,
wherein when the characters are input by said character inputting means, the selection portion is moved in association with the input characters.

19. An apparatus for inputting characters according to claim 18, wherein said character selecting means is moved in a right direction when the characters are input.

20. An apparatus for inputting characters according to claim 18, wherein said character selecting means deletes one of the input characters by pressing one of the plurality of buttons once.

21. An apparatus for inputting characters according to claim 20, wherein said selecting means is moved in a left direction when one of the input characters is deleted.

22. An apparatus for inputting characters according to claim 18, wherein the selected characters are displayed large.

23. A storage medium storing a program for carrying out a method for inputting characters by using a plurality of buttons, and enabling the program to be read, comprising:
a character selection module for selecting desired characters by scrolling a predetermined character string, and aligning the desired characters with an inputting position; and
a character inputting module for inputting the selected characters,
wherein the character selection module is moved in association with the input characters when the characters are input by said character inputting module.

24. An apparatus for inputting characters comprising:
a character information input area;
a display area for displaying information of a character to be selected on a character inputting position of the character information input area;
scrolling means for scrolling the information of the character to be selected in said display area; and
moving means for inputting, to the character information inputting position, character information displayed on a predetermined position of said display area by scrolling of said scrolling means, and moving said display area to a next character information inputting position.

25. An apparatus according to claim 24, wherein said moving means moves said display area to a character information inputting position immediately before when the character information is deleted.

26. An apparatus according to claim 24, wherein the character information in the predetermined position of said display area is displayed large.

27. An apparatus according to claim 24, wherein incremental search is carried out based on the character information in the predetermined position of said display area, and desired character information is input from a list displayed as a result thereof.

28. A method for inputting characters, comprising:
a scrolling step of scrolling information of a character to be selected in a display area for displaying the information of the character to be selected on a character inputting position of a character information inputting area; and
a moving step of inputting, to the character information inputting position, character information displayed on a predetermined position of the display area by scrolling of said scrolling step, and moving the display area to a next character information inputting position.

29. A method for inputting characters according to claim 28, wherein in said moving step, when the character information is deleted, the display area is moved to a character information inputting position immediately before.

30. A method for inputting characters according to claim 28, wherein the character information in the predetermined position of the display area is displayed large.

31. A method for inputting characters according to claim 28, wherein incremental search is carried out based on the character information in the predetermined position of the display area, and desired character information is input from a list displayed as a result thereof.

32. A storage medium for enabling a program to be read, the program being used to carry out a control method of an input apparatus, comprising:
a scrolling module for scrolling information of a character to be selected in a display area for displaying the information of the character to be selected in a character inputting position of a character information input area; and
a moving module for inputting, to the character information inputting position, character information displayed on a predetermined position of the display area by scrolling of said scrolling module, and moving the display area to a next character information inputting position.
